(19) United States
(12) Patent Application Publication
(10) Pub. No.: US 2011/0122007 A1
(43) Pub. Date: May 26, 2011

(54) SEMICONDUCTOR STORAGE DEVICE AND METHOD OF MANUFACTURING THEREOF

(75) Inventor: Seiji OKAMOTO, Yokohama (JP)

(73) Assignee: FUJITSU SEMICONDUCTOR LIMITED, Yokohama-shi (JP)

(21) Appl. No.: 12/950,577

(22) Filed: Nov. 19, 2010

(30) Foreign Application Priority Data
Nov. 20, 2009 (JP) 2009-264642

(51) Int. Cl. H03M 1/00; H03M 1/12

(52) U.S. Cl. 341/122; 341/156

(57) ABSTRACT

An analog-to-digital converter circuit includes: a plurality of sample-and-hold circuits configured to sample an analog signal; an analog-to-digital converter configured to convert the analog signal held by each of the plurality of sample-and-hold circuits into a digital signal; and a control circuit configured to output a control signal, wherein a pair of sample-and-hold circuits among the plurality of sample-and-hold circuits sample an analog signal in a first period and hold an analog signal sampled by another pair of sample-and-hold circuits in a second period prior to the first period based on the control signal.

### CROSS-REFERENCE TO RELATED APPLICATIONS

This application claims the benefit of priority from Japanese Patent Application No. 2009-264642 filed on Nov. 20, 2009, the entire contents of which are incorporated herein by reference.

### BACKGROUND

1. Field

The embodiments discussed herein relate to an analog-to-digital converter circuit.

2. Description of Related Art

A communication reception circuit may include a plurality of analog-to-digital converter (ADC) circuits for converting an analog input signal into a digital signal. For example, a radio reception circuit may include a quadrature detection circuit for down-converting a high-frequency input signal with a local-frequency signal and performing quadrature detection upon the down-converted signal, and an ADC circuit for converting an analog I signal and an analog Q signal, which have been extracted by the quadrature detection circuit, into a digital I signal and a digital Q signal, respectively.

Japanese Laid-open Patent Publication Nos. H3-220917 and 2006-54684 disclose related techniques.

### SUMMARY

According to one aspect of the embodiments, an analog-to-digital converter circuit includes: a plurality of sample-and-hold circuits configured to sample an analog signal; an analog-to-digital converter configured to convert the analog signal held by each of the plurality of sample-and-hold circuits into a digital signal; and a control circuit configured to output a control signal, wherein a pair of sample-and-hold circuits among the plurality of sample-and-hold circuits sample an analog signal in a first period and hold an analog signal sampled by another pair of sample-and-hold circuits in a second period prior to the first period, based on the control signal.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary ADC circuit;

FIG. 2 illustrates an exemplary ADC circuit;

FIG. 3 illustrates an exemplary operation of an ADC circuit;

FIG. 4 illustrates an exemplary sample-and-hold circuit;

FIG. 5 illustrates an exemplary ADC;

FIG. 6 illustrates an exemplary ADC circuit;

FIG. 7 illustrates an exemplary sample-and-hold circuit group; and

FIG. 8 illustrates an exemplary operation of an ADC circuit.

### DESCRIPTION OF EMBODIMENTS

An analog-to-digital converter (ADC) circuit includes a sample-and-hold circuit for sampling and holding an analog input signal and an analog-to-digital converter (ADC) for converting a sampled analog signal into a digital signal. An ADC circuit for an analog I signal and an ADC circuit for an analog Q signal may be provided set in parallel to each other.

When a common ADC circuit is used, a plurality of sample-and-hold circuits sample and hold analog input signals and the common ADC circuit time-divisionally converts the sampled analog input signals into digital output signals. Conversion from an analog signal into a digital signal is performed in a plurality of cycles.

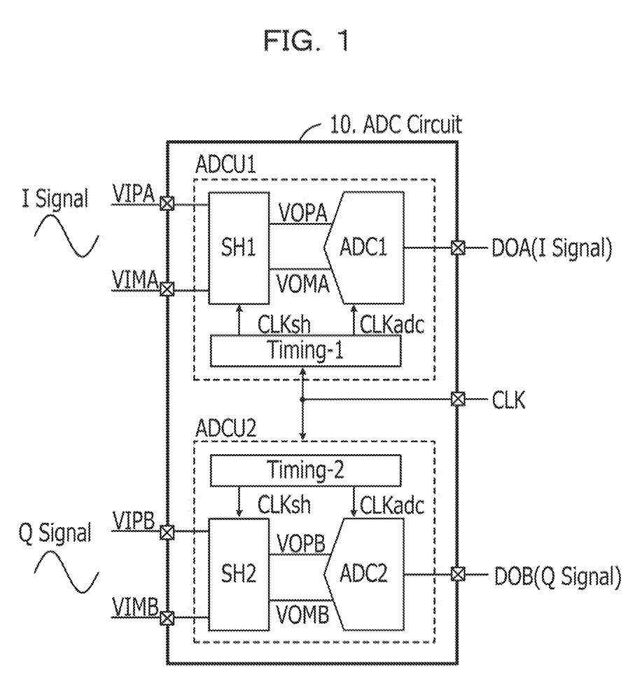

FIG. 1 illustrates an exemplary ADC circuit. An ADC circuit 10 includes a first pair of analog input terminals for receiving first analog input signals VIPA and VIMA, which are I signals, and a first ADC circuit ADCU1 for converting the first analog input signals VIPA and VIMA into a digital output signal DOA and outputting the digital output signal DOA. The first analog input signals VIPA and VIMA may be a differential signal.

Furthermore, the ADC circuit 10 includes a second pair of analog input terminals for receiving second analog input signals VIPB and VIMB corresponding to Q signals and a second ADC circuit ADCU2 for converting the second analog input signals VIPB and VIMB into a digital output signal DOB and outputting the digital output signal DOB. The second analog input signals VIPB and VIMB may be a differential signal.

The first ADC circuit ADCU1 includes a first sample-and-hold circuit SH1 for sampling and holding the first analog input signals, an analog-to-digital converter ADC1 for converting analog input signals VOPA and VOMA into a digital signal, and a timing control circuit Timing-1 for supplying control clock signals CLKadc and CLKsh in synchronization with a clock CLK. The second ADC circuit ADCU2 includes a second sample-and-hold circuit SH2 for sampling and holding the second analog input signals, an analog-to-digital converter ADC2 for converting analog input signals VOPB and VOMB into a digital signal, and a timing control circuit Timing-2 for supplying the control clock signals CLKadc and CLKsh in synchronization with the clock CLK.

The ADC circuit 10 illustrated in FIG. 1 includes the first ADC circuit ADCU1 for I signals and the second ADC circuit ADCU2 for Q signals. The first ADC circuit ADCU1 samples an analog input signal in a first clock cycle. In a second clock cycle, the sample-and-hold circuit SH1 holds the analog input signal, and the first ADC circuit ADCU1 converts the held analog input signal into a digital signal. The second ADC circuit ADCU2 samples an analog input signal in the first clock cycle. In the second clock cycle, the sample-and-hold circuit SH2 holds the analog input signal, and the second ADC circuit ADCU2 converts the held analog input signal into a digital signal. For example, every two clock cycles an analog input signal is sampled and held, and the sampled and held analog input signal is converted into a digital signal. When the first ADC circuit ADCU1 and the second ADC circuit ADCU2 are pipeline ADC circuits, the digital output signals DOA and DOB may be output from the first ADC circuit ADCU1 and the second ADC circuit ADCU2 respectively, after clock cycles corresponding to the number of pipelines elapse.

The ADC circuit 10 illustrated in FIG. 1 includes the first sample-and-hold circuit SH1 and the analog-to-digital converter ADC1 for I signals, and includes the second sample-and-hold circuit SH2 and the analog-to-digital converter ADC2 for Q signals.

In order to reduce an area, a common ADC circuit may be provided for the sample-and-hold circuits SH1 and SH2. In a first clock cycle, the sample-and-hold circuit SH1 samples the analog input signals VIPA and VIMA and the second sample-and-hold circuit SH2 samples the analog input signals VIPB and VIMB. In second and third clock cycles, the sample-and-hold circuit SH1 holds the analog input signals VIPA and VIMA, the sample-and-hold circuit SH2 holds the analog input signals VIPB and VIMB, and the common ADC circuit converts the held analog input signals into digital signals. Analog input signals may be sampled and held and the sampled and held analog input signals may be converted into digital signals every three clock cycles. An analog-to-digital conversion speed may be reduced.

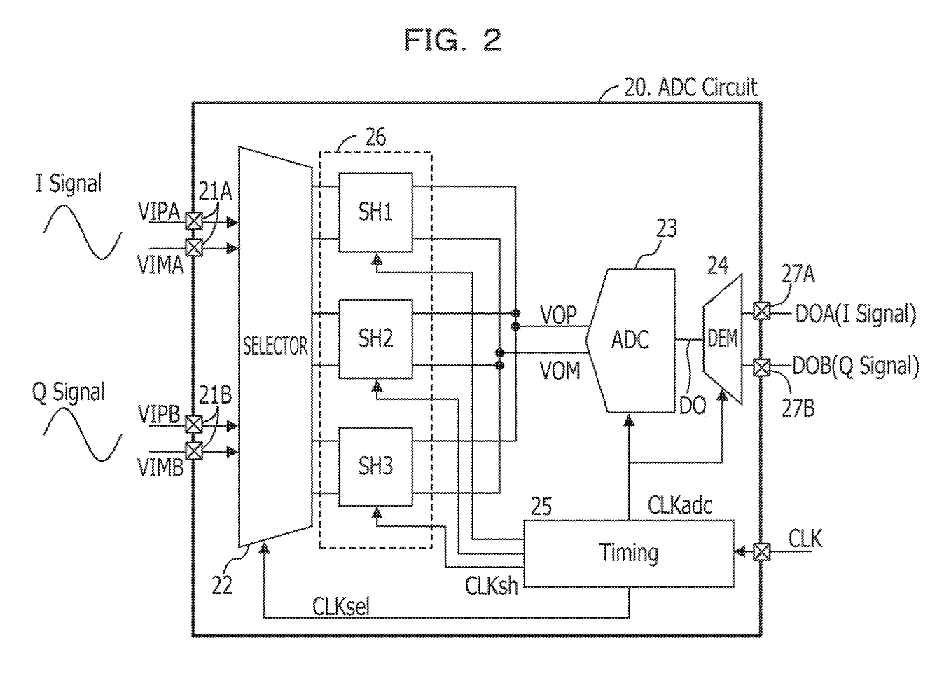

FIG. 2 illustrates an exemplary ADC circuit. An ADC circuit 20 illustrated in FIG. 2 includes a sample-and-hold circuit group 26 including three sample-and-hold circuits SH1, SH2, and SH3, and a common ADC 23 for the three sample-and-hold circuits.

For example, in each odd-numbered clock cycle, a pair of sample-and-hold circuits is selected from among the first sample-and-hold circuit SH1, the second sample-and-hold circuit SH2, and the third sample-and-hold circuit SH3, and the selected pair of sample-and-hold circuits samples the first analog input signals VIPA and VIMA and the second analog input signals VIPB and VIMB. For example, one of the selected sample-and-hold circuits holds a first analog input signal in an even-numbered clock cycle. The other one of the selected sample-and-hold circuits holds a second analog input signal in an odd-numbered clock cycle next to the even-numbered clock cycle. The held analog input signals are input into the common ADC 23 as outputs VOP and VOM of the sample-and-hold circuit SH. In each clock cycle, the common ADC 23 converts the held first or second analog input signal into a digital signal. In the case of a pipeline ADC circuit, the converted digital output signals DOA and DOB may be output after clock cycles corresponding to the number of pipelines elapse.

In the ADC circuit 20 illustrated in FIG. 2, the first analog input I signals VIPA and VIMA are input into a first pair 21A of input terminals and the second analog input Q signals VIPB and VIMB are input into a second pair 21B of input terminals. The first and second analog input signals may be differential signals. A selector 22 selects a pair of sample-and-hold circuits from among three sample-and-hold circuits, the sample-and-hold circuits SH1, SH2, and SH3. The first analog input signals are input from the first pair 21A of input terminals into the selected pair of sample-and-hold circuits, and the second analog input signals are input from the second pair 21B of input terminals into the selected pair of sample-and-hold circuits.

Every clock cycle, the common ADC 23 alternately converts the first and second analog input signals held by one of the sample-and-hold circuits SH1, SH2, and SH3 into a digital signal and outputs the converted digital signal. A demultiplexer 24 converts a serial digital output signal DO output from the common ADC 23 into parallel signals. The first digital output signal DOA and the second digital output signal DOB are output from output terminals 27A and 27B, respectively. A timing control circuit 25 generates a control clock signal CLKsel, CLKsh, or CLKadc in synchronization with the clock CLK and supplies it to the selector 22, the sample-and-hold circuits SH1, SH2, and SH3, the common ADC 23, or the demultiplexer 24.

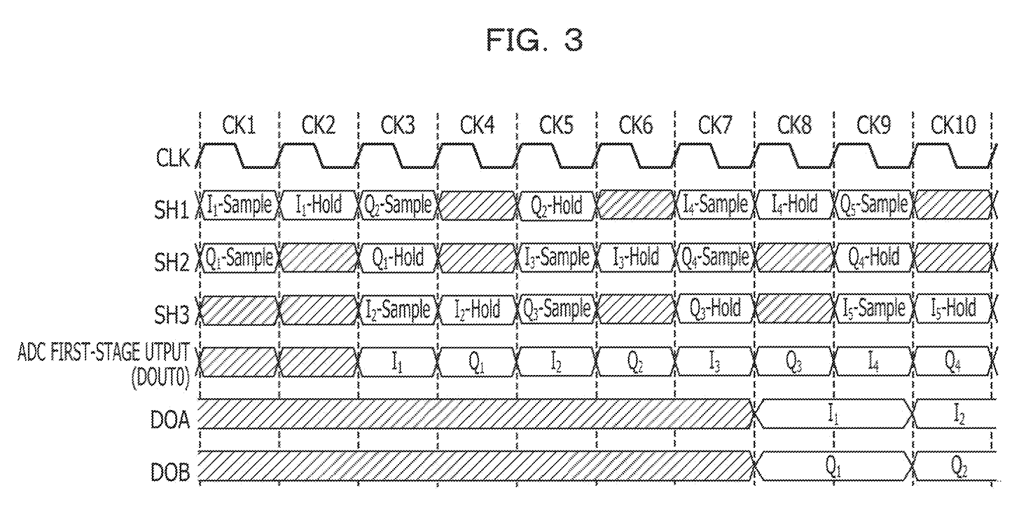

FIG. 3 illustrates an exemplary operation of an ADC circuit. The operation illustrated in FIG. 3 may be performed by the ADC circuit illustrated in FIG. 2. Referring to FIG. 3, SH1, SH2, and SH3 may represent operations of the sample-and-hold circuits SH1, SH2, and SH3 illustrated in FIG. 2, respectively. ADC first-stage output may represent a first-stage output of the common ADC 23 having a pipeline configuration, and DOA and DOB may represent digital output signals.

In a clock cycle CK1, the sample-and-hold circuits SH1 and SH2 are selected from among three sample-and-hold circuits, the sample-and-hold circuits SH1, SH2, and SH3, and sample a first analog input signal I₁ and a second analog input signal Q₁, respectively. In a next clock cycle CK2, the sample-and-hold circuit SH1 holds the first analog input signal I₁ and outputs the first analog input signal I₁ to output terminals VOP and VOM. At that time, the second sample-and-hold circuit SH2 is not in a sampling state and a holding state, and stores the second analog input signal Q₁. The common ADC 23 converts the held first analog input signal I₁ into a digital signal.

In a next clock cycle CK3, a first-stage circuit in the common ADC 23 outputs a digital signal I₁. In the clock cycle CK3, the second sample-and-hold circuit SH2 enters the holding state, holds the second analog input signal Q₁, and outputs the second analog input signal Q₁ to the output terminals VOP and VOM. The common ADC 23 converts the held second analog input signal Q₁ into a digital signal. In the clock cycle CK3, the sample-and-hold circuits SH3 and SH1 sample a first analog input signal I₂ and a second analog input signal Q₂, respectively. In the clock cycle CK3, one of the three sample-and-hold circuits holds the analog input signal sampled in the clock cycle CK1, and the other two of the three sample-and-hold circuits individually sample the first and second analog input signals. As a result, a sampling period is reduced, and an analog-to-digital conversion speed is increased.

In a clock cycle CK4, the first-stage circuit in the common ADC 23 outputs a digital signal Q₁. In the clock cycle CK4, the third sample-and-hold circuit SH3 holds the first analog input signal I₂ sampled in the clock cycle CK3. The common ADC 23 converts the held first analog input signal I₂ into a digital signal.

In a clock cycle CK5, for example, like in the clock cycle CK3, the first-stage circuit in the common ADC 23 outputs a digital signal I₂ and the sample-and-hold circuit SH1 holds the second analog input signal Q₂ and outputs the second analog input signal Q₂ to the output terminals VOP and VOM. The common ADC 23 starts analog-to-digital conversion. The sample-and-hold circuits SH2 and SH3 sample a first analog input signal I₃ and a second analog input signal Q₃, respectively.

An operation in each of clock cycles CK6 and CK8 may be substantially the same as or similar to that in, for example, the clock cycle CK4, and an operation in each of clock cycles CK7 and CK9 may be substantially the same as or similar to that in, for example, the clock cycle CK5.

The common ADC 23 has a four-stage pipeline configuration, and outputs a digital signal four clock cycles after starting analog-to-digital conversion. The common ADC 23 alternately performs analog-to-digital conversion upon the first analog input signal I and the second analog input signal Q, and alternately outputs the first digital output signal I and the second digital output signal Q. In a clock cycle CK8, digital output signals corresponding to the analog input signals I₁ and Q₁ that have been sampled in the clock cycle CK1 are output as the digital output signals DOA and DOB, respectively. In a clock cycle CK10, digital output signals corresponding to the analog input signals I₂ and Q₂ that have been sampled in the clock cycle CK3 are output as the digital output signals DOA and DOB, respectively.

In the odd-numbered clock cycles CK1, CK3, CK5, CK7, and CK9, a pair of sample-and-hold circuits selected from among the first sample-and-hold circuit SH1, the second sample-and-hold circuit SH2, and the third sample-and-hold circuit SH3 samples the first and second analog input signals. In the even-numbered clock cycles CK2, CK4, CK6, CK8, and CK10, one of the sample-and-hold circuits included in the pair holds the first analog input signal. In odd-numbered clock cycles next to the even-numbered clock cycles, the other one of the sample-and-hold circuits included in the pair holds the second analog input signal. In each clock cycle, the common ADC 23 converts the held first or second analog input signal into a digital signal. Every two clock cycles, two analog input signals are sampled by three sample-and-hold circuits SH. In each clock cycle, the common ADC 23 performs analog-to-digital conversion and outputs a digital output signal.

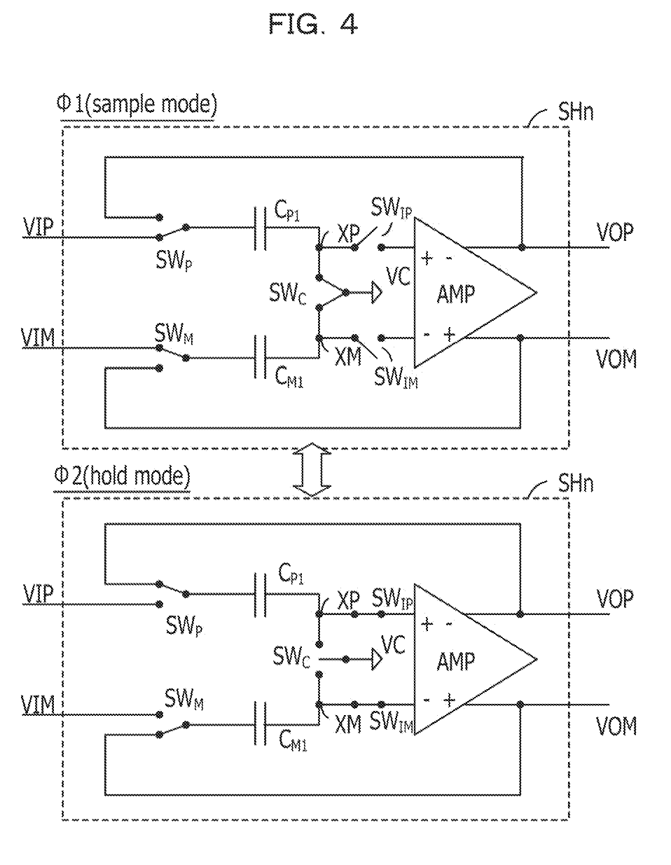

FIG. 4 illustrates an exemplary sample-and-hold circuit. FIG. 4 illustrates a sample mode φ1 and a hold mode φ2 of a sample-and-hold circuit SHn.

A sample-and-hold circuit includes sampling capacitors C_{P1} and C_{M1}, a differential output amplifier AMP, a pair of first switches SW_{P} and SW_{M}, a second switch SW_{C}, and a pair of third switches SW_{IP} and SW_{IM}. The pair of the first switches SW_{P} and SW_{M} individually couples input terminals for differential input signals VIP and VIM or output terminals for differential output signals VOP and VOM to the sampling capacitors C_{P1} and C_{M1}. The second switch SW_{C} couples an electrode XP of the sampling capacitor C_{P1} and an electrode XM of the sampling capacitor C_{M1} to a reference voltage VC. The pair of the third switches SW_{IP} and SW_{IM} individually couples the electrodes XP and XM to input terminals (+,−) of the amplifier AMP. A switched capacitor circuit may include the sampling capacitors C_{P1} and C_{M1} and a group of switches SW_{P}, SW_{M}, SW_{C}, SW_{IP}, and SW_{IM}.

In the sample mode φ1, the pair of the first switches SW_{P} and SW_{M} individually couples one electrode of each of the sampling capacitors C_{P1} and C_{M1} to the input terminals. The second switch SW_{C} couples the other electrodes XP and XM of the sampling capacitors C_{P1} and C_{M1} to the reference voltage VC. Voltages VIP-VC and VIM-VC are applied to the sampling capacitors C_{P1} and C_{M1}, respectively, so that an electric charge is stored in the sampling capacitors C_{P1} and C_{M1}. Each of the sampling capacitors C_{P1} and C_{M1} samples an analog input signal.

In the hold mode φ2, the pair of the first switches SW_{P} and SW_{M} individually couples one electrode of each of the sampling capacitors C_{P1} and C_{M1} to the output terminals. The second switch SW_{C} is in an off (open) state. The pair of the third switches SW_{IP} and SW_{IM} individually couples the other electrodes XP and XM of the sampling capacitors C_{P1} and C_{M1} to input terminals of the amplifier AMP. The amplifier AMP drives output voltages VOP and VOM so as to set the voltages of the other electrodes XP and XM to the reference voltage VC. As a result, the output voltages VOP and VOM are substantially the same as input voltages VIP and VIM, respectively. The amplifier AMP may output the analog input signals VIP and VIM to the output terminals VOP and VOM, respectively.

For example, when the switches SW_{P}, SW_{M}, SW_{C}, SW_{IP}, and SW_{IM} are in the open state and an electric charge is stored in the sample capacitors, another mode different from the sample mode and the hold mode illustrated in FIG. 4 may be set.

The sample-and-hold circuit SHn may include a circuit different from the circuit illustrated in FIG. 4. For example, the sample-and-hold circuit SHn may include a first capacitor between an input terminal of the amplifier illustrated in FIG. 4 and an analog input terminal and a second capacitor between the input terminal of the amplifier and an output terminal. At the time of sampling, an analog input voltage may be applied to the first capacitor. At the time of holding, a reference voltage may be applied to the first capacitor.

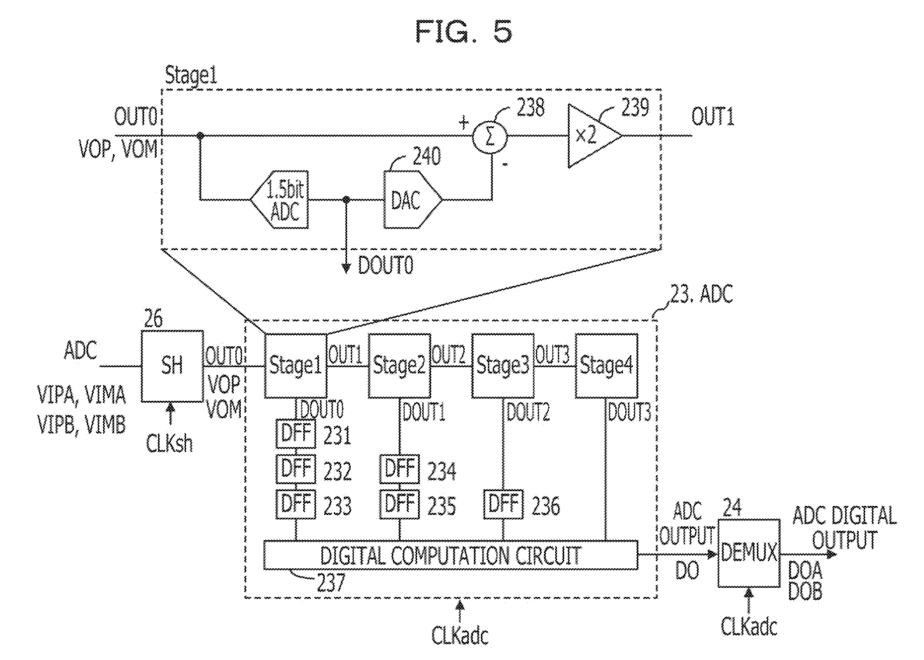

FIG. 5 illustrates an exemplary ADC. As illustrated in FIG. 2, an ADC circuit includes the sample-and-hold circuit group 26 including three sample-and-hold circuits SH1, SH2, and SH3, and an ADC 23 for converting differential output signals VOP and VOM (VOP-VOM) into a digital signal. The ADC 23 includes four conversion stages Stage1 to Stage4, delay flip flops 231 to 236 for storing outputs DOUT0 to DOUT2 of the conversion stages, and a digital computation circuit 237.

The conversion stage Stage1 includes a 1.5-bit ADC, a DAC 240, a subtracter 238, and an amplifier 239. The 1.5-bit ADC converts a differential analog input signal OUT0 (VOP-VOM) into the digital signal DOUT0 that is a 1.5-bit signal. The DAC 240 generates a positive reference voltage +Vref, a negative reference voltage −Vref, or 0 V in accordance with the digital signal DOUT0. The subtracter 238 subtracts the output of the DAC 240 from the differential analog input signal OUT0. The amplifier 239 doubles the output of the subtracter 238.

For example, the 1.5-bit ADC detects whether the differential analog input signal OUT0 has a gray area voltage (output 01) close to ±0 V, which is a middle value between the reference voltages −Vref and +Vref, a voltage (output 10) higher than the gray area voltage, or a voltage (output 00) lower than the gray area voltage, and outputs 00, 01, or 10 as the output DOUT0. When the output DOUT0 is 00, the DAC 240 outputs the voltage −Vref. When the output DOUT0 is 01, the DAC 240 outputs 0 V. When the output DOUT0 is 10, the DAC 240 outputs the voltage +Vref. When the output DOUT0 that is an output of the 1.5-bit ADC is 00, an output OUT1 may be a voltage obtained by adding the reference voltage Vref to the input signal OUT0 and doubling a result of the addition. When the output DOUT0 is 01, the output OUT1 may be a voltage obtained by doubling the input signal OUT0. When the output DOUT0 is 10, the output OUT1 may be a voltage obtained by subtracting the reference voltage Vref from the input signal OUT0 and doubling a result of the subtraction.

The conversion stage Stage2 calculates the lower-order digital signal DOUT1 corresponding to the output OUT1 of the conversion stage Stage1. The circuit configuration of the conversion stages Stage2, Stage3, and Stage4 may be substantially the same as or similar to that of the conversion stage Stage1, and may output a 2-bit (1.5-bit) digital signal.

The outputs DOUT0, DOUT1, DOUT2, and DOUT3 of the conversion stages Stage1, Stage2, Stage3, and Stage4 are transferred via the delay flip-flops 231 to 236 in synchronization with the clock signal CLKadc, and are input into the digital computation circuit 237 three clock cycles later. The outputs DOUT0 to DOUT3 may also be input into the digital computation circuit 237 contemporaneously. The digital computation circuit 237 performs computation on the 2-bit digital outputs DOUT0 to DOUT3 so as to output a 5-bit digital output D0. A computation method used in a 1.5-bit ADC may be used.

As illustrated in FIG. 3, in the clock cycle CK3, the most significant digital output of the signal I₁ is output as the output DOUT0 of the first conversion stage Stage1. Although not illustrated, in the clock cycles CK4, CK5, and CK6, the lower-order 2-bit (1.5-bit) digital outputs of the signal I₁ are output as the outputs DOUT1, DOUT2, and DOUT3 of the subsequent conversion stages Stage2, Stage3, and Stage4, respectively. In the clock cycle CK4, the most significant 2-bit (1.5-bit) digital output of the signal Q₁ is output as the output DOUT0 of the first conversion stage Stage1. Although not illustrated, in the clock cycles CK5, CK6, and CK7, the lower-order digital outputs of the signal Q₁ are output as the outputs DOUT1, DOUT2, and DOUT3 of the subsequent conversion stages Stage2, Stage3, and Stage4, respectively.

In the clock cycles CK8 and CK9, the demultiplexer 24 outputs in parallel the digital output signals DOA and DOB corresponding to the input signals I₁ and Q₁ that have been serially input. Subsequently, every two clock cycles, the digital output signals DOA and DOB corresponding to input signals I₂ and Q₂, I₃ and Q₃, and so on, are output in parallel.

For example, a 1-bit, 2-bit, or n-bit ADC may be used. The DAC 240 generates an analog voltage in accordance with the digital output DOUT of the ADC. The pipeline ADC 23 may include an ADC and a DAC.

The common ADC 23 may include a flash ADC or a successive approximation ADC. These ADCs may perform analog-to-digital conversion in each clock cycle.

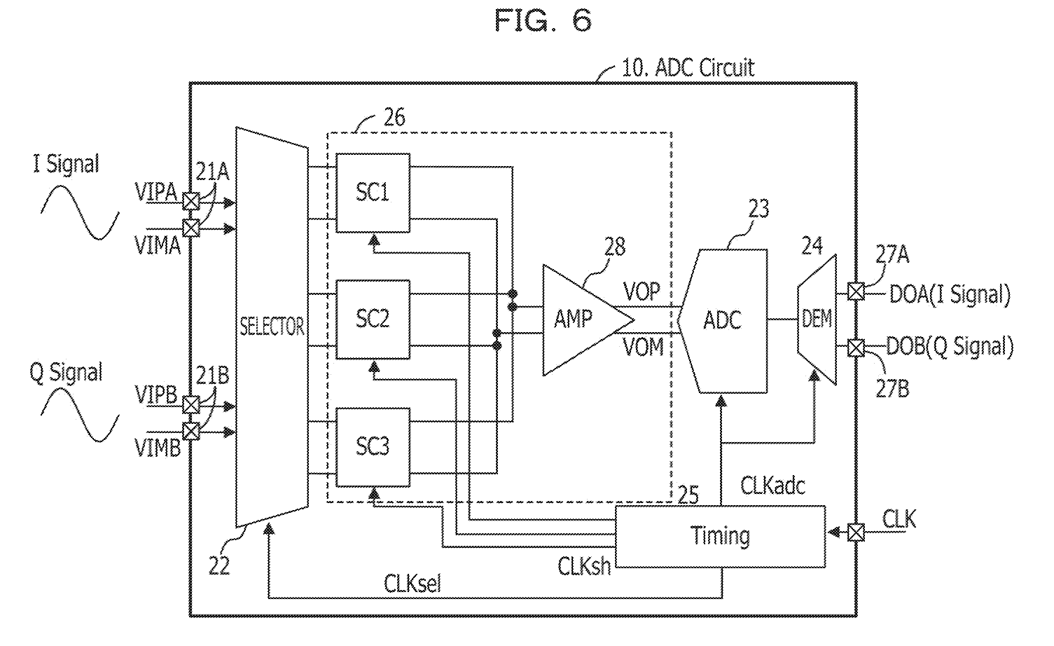

FIG. 6 illustrates an exemplary ADC circuit. The ADC circuit 10 illustrated in FIG. 6 includes the analog input terminals 21A and 21B, the selector 22, the sample-and-hold circuit group 26, the common ADC 23, the demultiplexer 24, and the timing control circuit 25. The sample-and-hold circuit group 26 included in the ADC circuit illustrated in FIG. 6 includes switched capacitor circuits SC1, SC2, and SC3 and a differential output amplifier 28. The differential output amplifier 28 may be a common differential output amplifier for the switched capacitor circuits SC1, SC2, and SC3.

The sample-and-hold circuit group 26 included in the ADC circuit illustrated in FIG. 2 includes the sample-and-hold circuits SH1, SH2, and SH3. Each of the sample-and-hold circuits SH1, SH2, and SH3 includes a switched capacitor circuit and a differential output amplifier. In the sample-and-hold circuit group 26 included in the ADC circuit illustrated in FIG. 6, a common differential output amplifier is provided. The common differential output amplifier time-divisionally performs a holding operation every clock cycle for three switched capacitor circuits.

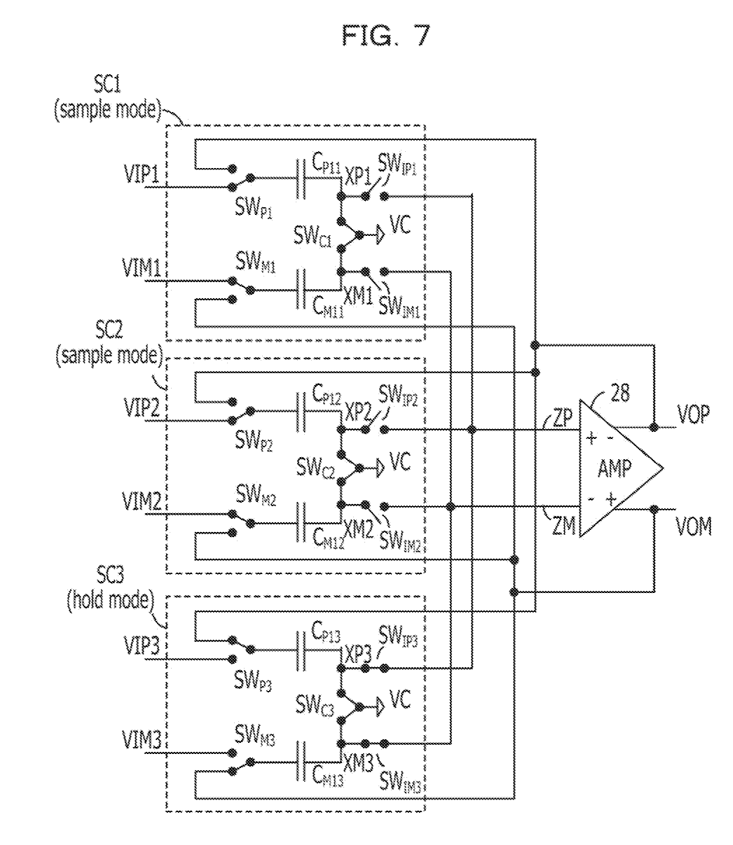

FIG. 7 illustrates an exemplary sample-and-hold circuit group. The sample-and-hold circuit group illustrated in FIG. 7 may be the sample-and-hold circuit group 26 in the ADC circuit illustrated in FIG. 5. The sample-and-hold circuit group illustrated in FIG. 7 includes the first switched capacitor circuit SC1, the second switched capacitor circuit SC2, the third switched capacitor circuit SC3, and the differential output amplifier 28.

The configuration of the switched capacitor circuits SC1, SC2, and SC3 may be substantially the same as or similar to that of the sample-and-hold circuit illustrated in FIG. 4. The first switched capacitor circuit SC1 includes sampling capacitors C_{P11} and C_{M11}, a pair of first switches SW_{P1} and SW_{M1} for individually coupling input terminals for differential input signals VIP1 and VIM1 or output terminals for the differential output signals VOP and VOM to the sampling capacitors C_{P11} and C_{M11}, a second switch SW_{C1} for coupling an electrode XP1 of the sampling capacitor C_{P11} and an electrode XM1 of the sampling capacitor C_{M11} to the reference voltage VC, and a pair of third switches SW_{IP1} and SW_{IM1} for individually coupling the electrodes XP1 and XM1 to input terminals ZP and ZM of the differential output amplifier 28. The configuration of the switched capacitor circuits SC2 and SC3 may be substantially the same as or similar to that of the switched capacitor circuit SC1.

For example, the first switched capacitor circuit SC1 and the second switched capacitor circuit SC2 may be in the sample mode and the third switched capacitor circuit SC3 may be in the hold mode. In the first switched capacitor circuit SC1, the first switches SW_{P1} and SW_{M1} couple one electrode of each of the sampling capacitors C_{P11} and C_{M11} to the input signals VIP1 and VIM1, respectively, and the second switch SW_{C1} couples the other electrodes of the sampling capacitors C_{P11} and C_{M11} to the reference voltage VC. In the second switched capacitor circuit SC2, first switches SW_{P2} and SW_{M2} connect one electrode of each of the sampling capacitors C_{P12} and C_{M12} to input signals VIP2 and VIM2, respectively, and a second switch SW_{C2} couples the other electrodes of the sampling capacitors C_{P12} and C_{M12} to the reference voltage VC. Analog input voltages VIP1-VC, VIM1-VC, VIP2-VC, and VIM2-VC are applied to the sampling capacitors C_{P11}, C_{M11}, C_{P12}, and C_{M12}, respectively, so that an electric charge is stored in these sampling capacitors. A sampling capacitor samples an analog input signal.

In the third switched capacitor circuit SC3, first switches SW_{P3}, SW_{M3}, SW_{IP3}, and SW_{IM3} individually couple one electrode of each of the sampling capacitors C_{P13} and C_{M13} to the output signals VOP and VOM and individually couple the other electrode XP3 of the sampling capacitor C_{P13} and the other electrode XM3 of the sampling capacitor C_{M13} to input terminals ZP and ZM of the differential output amplifier 28. The third switched capacitor circuit SC3 enters the hold state, and analog input signals sampled by the sampling capacitors C_{P13} and C_{M13} are output from the differential output amplifier 28.

Each of the first switched capacitor circuit SC1 and the second switched capacitor circuit SC2 samples an analog input signal. The third switched capacitor circuit SC3 and the differential output amplifier 28 hold the sampled analog input signals as the output signals VOP and VOM.

The configuration of the common ADC 23 included in the ADC circuit 10 illustrated in FIG. 6 may be substantially the same as or similar to that of the common ADC 23 illustrated in FIG. 5, for example.

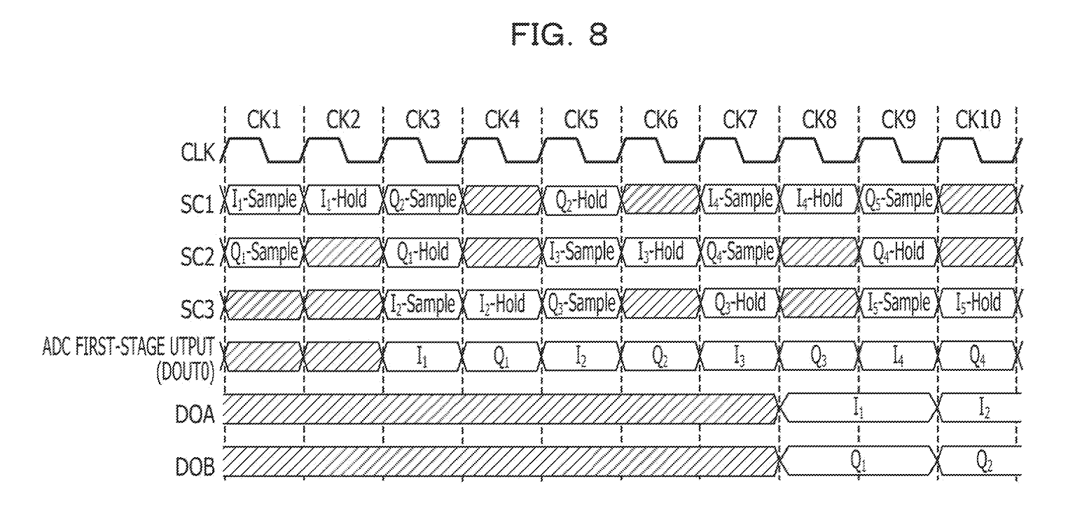

FIG. 8 illustrates an exemplary operation of an ADC circuit. FIG. 8 illustrates operational states of the switched capacitor circuits SC1, SC2, and SC3, a digital output signal DOUT0 of a first conversion stage in the common ADC 23, and a digital output signals DOA and DOB.

In the clock cycle CK1, the switched capacitor circuits SC1 and SC2 sample the first analog input signal I₁ and the second analog input signal Q₁, respectively. In the clock cycle CK2, the switched capacitor circuit SC1 in the hold state outputs the sampled first analog input signal I₁ to the output terminals VOP and VOM of the differential output amplifier 28. At that time, the switched capacitor circuit SC2 is not in the sample state and the hold state, and three switches included therein are in the open state. The common ADC 23 receives the first analog input signal I₁ from the differential output amplifier 28 and starts analog-to-digital conversion.

In the clock cycle CK3, a first-stage circuit in the common ADC 23 outputs the digital signal I₁. In the clock cycle CK3, the switched capacitor circuit SC2 in the hold state outputs the sampled second analog input signal Q₁ to the output terminals VOP and VOM of the differential output amplifier 28. The common ADC 23 receives the second analog input signal Q₁ and starts analog-to-digital conversion. In the clock cycle CK3, the switched capacitor circuits SC3 and SC1 sample the first analog input signal I₂ and the second analog input signal Q₂, respectively. In the clock cycle CK3, while one of three switched capacitor circuits holds the analog input signal sampled in the clock cycle CK1, the remaining switched capacitor circuits individually sample new first and second analog input signals. A sampling period may be reduced and an analog-to-digital conversion speed may be increased.

In the clock cycle CK4, the first-stage circuit in the common ADC 23 outputs the digital signal Q₁. In the clock cycle CK4, the third switched capacitor circuit SC3 outputs the first analog input signal I₂ sampled in the clock cycle CK3 to the differential output amplifier 28. The common ADC 23 receives the first analog input signal I₂ and starts analog-to-digital conversion.

Similar to the clock cycle CK3, in the clock cycle CK5, the first-stage circuit in the common ADC 23 outputs the digital signal I₂ and the switched capacitor circuit SC1 is in the hold state. The differential output amplifier 28 outputs the second analog input signal Q₂ to the output terminals VOP and VOM, and the common ADC 23 starts analog-to-digital conversion. The switched capacitor circuits SC2 and SC3 sample the first analog input signal I₃ and the second analog input signal Q₃, respectively.

An operation in the clock cycles CK6 and CK8 may be substantially the same as or similar to that in the clock cycle CK4. An operation in the clock cycles CK7 and CK9 may be substantially the same as or similar to that in the clock cycle CK5.

The common ADC 23 has a four-stage pipeline configuration, and outputs a digital signal four clock cycles after starting analog-to-digital conversion. The common ADC 23 alternately performs analog-to-digital conversion upon a first analog input signal I and a second analog input signal Q and alternately outputs a first digital output signal I and a second digital output signal Q. In the clock cycle CK8, digital output signals corresponding to the analog input signals I₁ and Q₁ sampled in the clock cycle CK1 are output as the output signals DOA and DOB, respectively. In the clock cycle CK10, digital output signals corresponding to the analog input signals I₂ and Q₂ sampled in the clock cycle CK3 are output as the output signals DOA and DOB, respectively.

In the odd-numbered clock cycles CK1, CK3, CK5, CK7, and CK9, a pair of switched capacitor circuits selected from among the first switched capacitor circuit SC1, the second switched capacitor circuit SC2, and the third switched capacitor circuit SC3 samples the first and second analog input signals. In the even-numbered clock cycles CK2, CK4, CK6, CK8, and CK10, one of the switched capacitor circuits included in the pair holds the first analog input signal. In odd-numbered clock cycles next to the even-numbered clock cycles, the other one of the switched capacitor circuits included in the pair holds the second analog input signal. In each clock cycle, the common ADC 23 converts the first or second analog input signal into a digital signal. Three switched capacitor circuits SC are provided, and two analog input signals are sampled every two clock cycles. In each clock cycle, the common ADC 23 converts a sampled analog input signal into a digital output signal and outputs the digital output signal.

Example embodiments of the present invention have now been described in accordance with the above advantages. These examples are merely illustrative of the invention. Many variations and modifications will be apparent to those skilled in the art.

1. An analog-to-digital converter circuit comprising:
a plurality of sample-and-hold circuits configured to sample an analog signal;
an analog-to-digital converter configured to convert the analog signal held by each of the plurality of sample-and-hold circuits into a digital signal; and
a control circuit configured to output a control signal,
wherein a pair of sample-and-hold circuits among the plurality of sample-and-hold circuits sample an analog signal in a first period and hold an analog signal sampled by another pair of sample-and-hold circuits in a second period prior to the first period, based on the control signal.

2. The analog-to-digital converter circuit according to claim 1,
wherein the plurality of sample-and-hold circuits include a first sample-and-hold circuit, a second sample-and-hold circuit, and a third sample-and-hold circuit,
the first sample-and-hold circuit and the second sample-and-hold circuit sample a first analog signal and a second analog signal, respectively, in a first clock cycle,
the first sample-and-hold circuit holds the first analog signal in a second clock cycle, and,
the second sample-and-hold circuit holds the second analog signal and the third sample-and-hold circuit, and the first sample-and-hold circuit sample a third analog signal and a fourth analog signal, respectively, in a third clock cycle.

3. The analog-to-digital converter circuit according to claim 2, wherein the first analog signal and the second analog signal includes an I signal and a Q signal t subjected to quadrature detection.

4. The analog-to-digital converter circuit according to claim 1, wherein the analog-to-digital converter sequentially performs conversion into the digital signal starting from a higher-order bit to a lower-order bit of the digital signal in synchronization with a clock signal.

5. The analog-to-digital converter circuit according to claim 2, further comprising
a demultiplexer configured to output a first digital signal corresponding to the first analog signal and a second digital signal corresponding to the second analog signal, which are output from the analog-to-digital converter in parallel in synchronization with a clock signal.

6. The analog-to-digital converter circuit according to claim 2, further comprising
a selector configured to select one of the first analog signal and the second analog signal and output the selected analog signal to one of the plurality of sample-and-hold circuits.

7. The analog-to-digital converter circuit according to claim 2,
wherein the first sample-and-hold circuit, the second sample-and-hold circuit, and the third sample-and-hold circuit include:
a first sampling capacitor, a second sampling capacitor, and a third sampling capacitor configured to store an electric charge in accordance with the first analog signal and the second analog signal in a sampling period, respectively; and
an amplifier, coupled to the first sampling capacitor, the second sampling capacitor, and the third sampling capacitor, configured to output a signal in accordance with an electric charge stored in a sampling capacitor in a holding period.

8. An analog-to-digital converter circuit comprising:
a first sample-and-hold circuit, a second sample-and-hold circuit, and a third sample-and-hold circuit configured to sample a first analog input signal or a second analog input signal; and
an analog-to-digital converter, coupled to the first sample-and-hold circuit, the second sample-and-hold circuit and third sample-and-hold circuits, configured to convert the first analog input signal or the second analog input signal into a digital signal, and
wherein the first sample-and-hold circuit and the second sample-and-hold circuit sample the first analog input signal and the second analog input signal respectively in a first clock cycle,
the first sample-and-hold circuit holds the first analog input signal in a second clock cycle,
the second sample-and-hold circuit holds the second analog input signal and the third sample-and-hold circuit and the first sample-and-hold circuit sample a third analog input signal and a fourth analog input signal, respectively, in a third clock cycle,
the third sample-and-hold circuit holds the third analog input signal in a fourth clock cycle,
the first sample-and-hold circuit holds the fourth analog input signal and the second sample-and-hold circuit and the third sample-and-hold circuit sample a fifth analog input signal and a sixth analog input signal, respectively, in a fifth clock cycle, and
the second sample-and-hold circuit holds the fifth analog input signal in a sixth clock cycle.

9. The analog-to-digital converter circuit according to claim 8,
wherein the first cycle to the sixth clock cycle are repeated, and
wherein one of the first analog input signal is converted to the sixth analog input signal.
